(19) United States
(12) Patent Application Publication
(10) Pub. No.: US 2026/0121138 A1
(43) Pub. Date: Apr. 30, 2026

(54) BATTERY SYSTEM

(71) Applicant: TOYOTA JIDOSHA KABUSHIKI KAISHA, Toyota-shi (JP)

(72) Inventor: Yoshiki TSUCHIDA, Nagoya-shi (JP)

(73) Assignee: TOYOTA JIDOSHA KABUSHIKI KAISHA, Toyota-shi (JP)

(21) Appl. No.: 19/187,021

(22) Filed: Apr. 23, 2025

(30) Foreign Application Priority Data
Sep. 12, 2024 (JP) 2024-158143

(51) Int. Cl. H01M 10/44; G01R 31/3835; H02J 3/32

(52) U.S. Cl. CPC H01M 10/441; G01R 31/3835; H02J 3/32; H02J 2101/24; H02J 2105/42

(57) ABSTRACT

A battery system includes a plurality of battery packs that is connected, in parallel to one another, to an external system. The battery packs are connected, in parallel to one another, to the external system through corresponding DC-DC converters. A control device discharges a first battery pack by operating the DC-DC converters so as to supply electricity from the first battery pack to other battery packs. After the discharge of the first battery pack, the control device charges the first battery pack by operating the DC-DC converters so as to supply electricity from the other battery packs to the first battery pack. The control device calculates a full charge capacity of the first battery pack based on an integrated amount of a current that has been charged to the first battery pack.

### CROSS-REFERENCE TO RELATED APPLICATION

This application claims priority to Japanese Patent Application No. 2024-158143 filed on Sep. 12, 2024. The disclosure of the above-identified application, including the specification, drawings, and claims, is incorporated by reference herein in its entirety.

### BACKGROUND

### 1. Technical Field

The present disclosure relates to a battery system.

### 2. Description of Related Art

Japanese Unexamined Patent Application Publication No. 2015-195653 (JP 2015-195653 A) describes a technology that estimates a battery capacity of a secondary battery in a battery system in which a plurality of secondary batteries is connected in parallel. In JP 2015-195653 A, one of the secondary batteries is set as a priority battery and only the priority battery is discharged or charged to thereby estimate the battery capacity of the priority battery.

### SUMMARY

In JP 2015-195653 A, the secondary batteries connected in parallel are connected to a charge circuit and a discharge circuit that they share. Electricity is discharged from the priority battery to a load by operating the shared charge circuit and discharge circuit. When electricity is discharged from the priority battery to estimate the battery capacity of the priority battery, an amount of electricity stored in the battery system decreases. This creates a concern that when a discharge request is made to the battery system after the estimation of the battery capacity, a requested amount of electricity may fail to be discharged.

An object of the present disclosure is to avoid a decrease in an amount of electricity stored in a battery system when measuring a full charge capacity of a battery.

A battery system of the present disclosure is a battery system that performs charge and discharge between the battery system and an external system. The battery system includes: a plurality of battery packs that is connected, in parallel to one another, to the external system; a plurality of DC-DC converters that is provided so as to correspond to the battery packs and is each disposed in a power line connecting the corresponding battery pack with the external system; and a control device that controls the DC-DC converters. The control device discharges a first battery pack selected from the battery packs until a state of charge (SOC) of the first battery pack becomes equal to or lower than a first predetermined value by operating the DC-DC converters corresponding respectively to the first battery pack and other battery packs so as to supply electricity from the first battery pack to the other battery packs. After this discharge, the control device charges the first battery pack until the SOC of the first battery pack becomes equal to or higher than a second predetermined value by operating the DC-DC converters so as to supply electricity from the other battery packs to the first battery pack. The control device calculates a full charge capacity of the first battery pack based on the electricity that has been charged to the first battery pack during this charge.

In this configuration, the battery system includes the battery packs that are connected, in parallel to one another, to the external system. In the power line connecting the battery packs with the external system, the DC-DC converters are disposed. The DC-DC converters are respectively provided for the battery packs. The control device controls the DC-DC converters. The control device discharges a first battery pack selected from the battery packs until the SOC of the first battery pack becomes equal to or lower than the first predetermined value by operating the DC-DC converters so as to supply electricity from the first battery pack to the other battery packs. After the discharge of the first battery pack, the control device charges the first battery pack until the SOC of the first battery pack becomes equal to or higher than the second predetermined value by operating the DC-DC converters so as to supply electricity from the other battery packs to the first battery pack. The control device calculates the full charge capacity of the first battery pack based on the electricity that has been charged to the first battery pack while the SOC of the first battery pack has changed from the first predetermined value to the second predetermined value. The full charge capacity of the first battery pack is obtained by exchanging electricity among the battery packs included in the battery system so as to charge and discharge the first battery pack. Thus, a decrease in the amount of electricity stored in the battery system can be avoided when measuring the full charge capacity of a battery pack.

In the battery system of the present disclosure, the full charge capacity of a first battery pack may be calculated based on electricity during discharge of the first battery pack. In this case, the control device charges a first battery pack selected from the battery packs until the SOC of the first battery pack becomes equal to or higher than a third predetermined value by operating the DC-DC converters so as to supply electricity from the other battery packs to the first battery pack. After the charge of the first battery pack, the control device discharges the first battery pack until the SOC of the first battery pack becomes equal to or lower than a fourth predetermined value by operating the DC-DC converters so as to supply electricity from the first battery pack to the other battery packs. The control device calculates the full charge capacity of the first battery pack based on the electricity that has been discharged from the first battery pack while the SOC of the first battery pack has changed from the third predetermined value to the fourth predetermined value.

In this configuration, the full charge capacity of the first battery pack is obtained by exchanging electricity among the battery packs included in the battery system. Thus, a decrease in the amount of electricity stored in the battery system can be avoided when measuring the full charge capacity of a battery pack.

The SOC of the first battery pack may be estimated based on a voltage of the first battery pack.

In this configuration, the SOC of the first battery pack can be estimated based on SOC-OCV (open circuit voltage) characteristics.

According to the present disclosure, a decrease in an amount of electricity stored in a battery system can be avoided when measuring a full charge capacity of a battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a battery system according to an embodiment;

FIG. 2 is a flowchart showing one example of a full charge capacity calculation process that is executed in a control device;

FIG. 3 is a graph illustrating SOC-OCV characteristics;

FIG. 4 is a flowchart showing one example of a full charge capacity calculation process that is executed in the control device in Embodiment 2; and

FIG. 5 is a schematic configuration diagram of a battery system in a modified example.

### DETAILED DESCRIPTION OF EMBODIMENTS

Embodiments of the present disclosure will be described in detail below with reference to the drawings. The same or equivalent parts in the drawings will be denoted by the same reference signs and description thereof w ill not be repeated.

### Embodiment 1

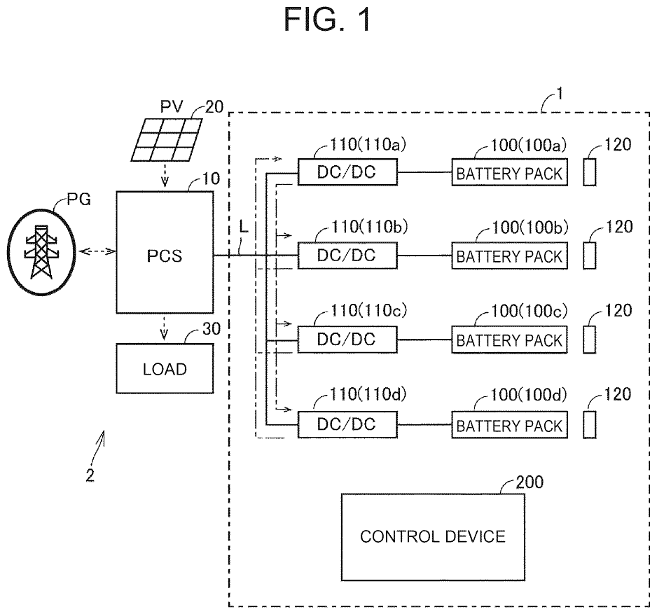

FIG. 1 is a schematic configuration diagram of a battery system 1 according to the embodiment. As shown in FIG. 1, the battery system 1 is connected to an external system 2 by a power line L. The battery system 1 can be supplied with electricity from the external system 2 as well as can discharge electricity to the external system 2. The battery system 1 includes a plurality of battery packs 100. In the present embodiment, it includes four battery packs 100a to 100d. The number of the battery packs 100 is arbitrary, and may be 10 or may be 20.

The battery pack 100 is an assembled battery in which a plurality of single batteries (battery cells) is connected, for example, in series. The battery cells may be ternary lithium-ion batteries (hereinafter referred to also as “NMC batteries”) or may be iron phosphate-based lithium-ion batteries (hereinafter referred to also as “LFP batteries”). Or the battery cells may be nickel-metal hydride batteries. The battery pack 100 may be a battery pack (battery module) that has been previously installed in a vehicle.

Referring to FIG. 1, the four battery packs 100a to 100d are connected, in parallel to one another, to the external system 2. In the power line L that connects the battery packs 100a to 100d to the external system, DC-DC converters 110 (110a to 110d) are respectively provided for the battery packs 100a to 100d. The DC-DC converters 110a to 110d are bidirectional DC-DC converters and controlled by a control device 200. The DC-DC converters 110a to 110d control charge and discharge of the corresponding battery packs 100a to 100d.

For each of the battery packs 100a to 100d, a monitoring module 120 is provided. The monitoring module 120 detects a voltage VB [V], a current IB [A], and a temperature TB of the corresponding one of the battery packs 100a to 100d and outputs the detected values to the control device 200. The current IB has positive and negative signs indicating flow directions, and a current charged to the battery pack 100 (charge current) is detected as a positive (+) value while a current discharged from the battery pack 100 (discharge current) is detected as a negative (−) value. The monitoring module 120 calculates an SOC of the corresponding one of the battery packs 100a to 100d and outputs the calculated SOC to the control device 200. The SOC of the battery pack 100 may be calculated in the control device 200. The SOC is a charge state of the battery pack 100, and is defined with a fully charged state as SOC=100 [%] and a completely discharged state as SOC=0 [%].

The external system 2 includes a power conditioning system (PCS) 10, a photovoltaic power generation device 20, a load 30, and a power grid PG. The battery packs 100a to 100d are connected, in parallel to one another, to the PCS 10 through the respective DC-DC converters 110a to 110d.

The PCS 10 is a power conversion device capable of both of AC-DC conversion (conversion from an alternating current to a direct current) and DC-AC conversion (conversion from a direct current to an alternating current). For example, the PCS 10 receives direct-current electricity from the photovoltaic power generation device 20. The PCS 10 supplies alternating-current electricity to the load 30. The load 30 includes electrical products used in households (e.g., air conditioners and lighting apparatuses). The PCS 10 exchanges alternating-current electricity between itself and the power grid PG.

The control device 200 includes a processor and a memory, and controls the battery system 1 by receiving commands from the PCS 10. In the present embodiment, the control device 200 calculates a full charge capacity of the battery pack 100 by controlling the DC-DC converters 110a to 110d.

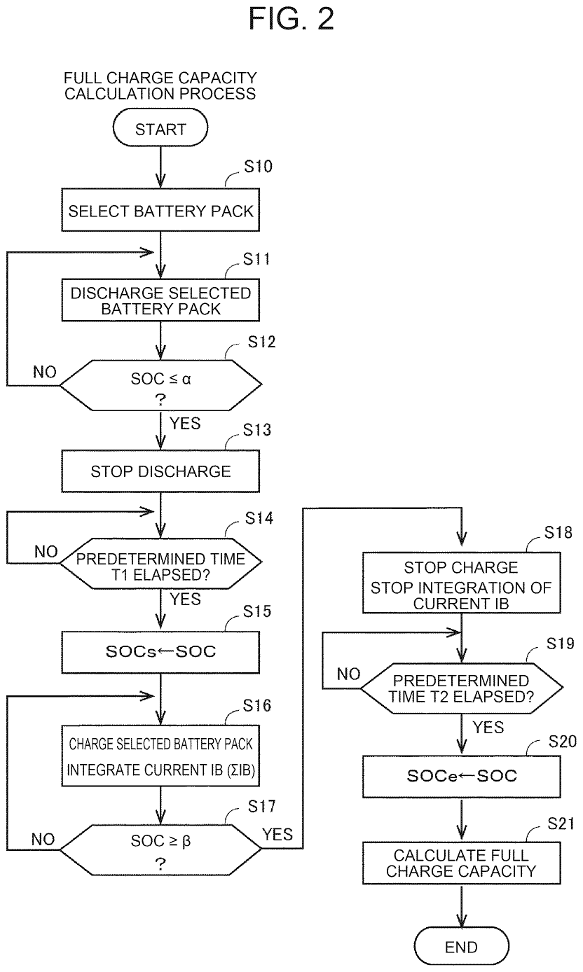

FIG. 2 is a flowchart showing one example of a full charge capacity calculation process that is executed in the control device 200. This flowchart is executed when exchange of electricity is not being performed between the battery system 1 and the external system 2 (PCS 10) (when charge and discharge are not being performed between the battery system 1 and the external system 2).

In step (hereinafter, “step” will be abbreviated as “S”) 10, a battery pack 100 of which the full charge capacity is to be measured is selected. To select the battery pack 100, any method can be used that can, for example, sequentially measure the full charge capacities of the battery packs 100a to 100d. When the full charge capacity of only a specific battery pack 100 is to be measured, that battery pack 100 of which the full charge capacity is to be measured may be selected. In the present embodiment, first, the battery pack 100a is selected as the battery pack of which the full charge capacity is to be measured.

In S11, discharge of the selected battery pack 100 (in the current process, the battery pack 100a) is executed. The control device 200 operates the DC-DC converters 110a to 110d so as to supply the electricity stored in the battery pack 100a to the battery packs 100b to 100d as indicated by the long dashed short dashed line in FIG. 1. Thus, the electricity discharged from the battery pack 100a is charged to the battery packs 100b to 100d. In the current process, the battery pack 100a corresponds to “first battery pack” of the present disclosure, and the battery packs 100b to 100d correspond to one examples of “the other battery packs” of the present disclosure.

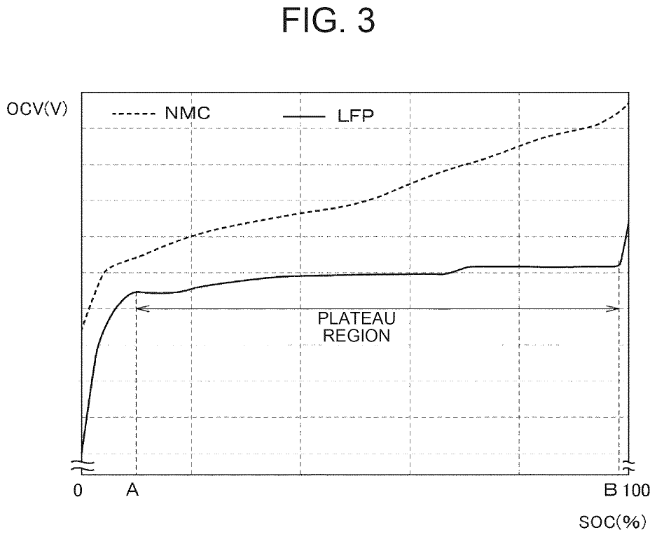

In the subsequent S12, it is determined whether the SOC of the battery pack 100a is equal to or lower than a predetermined value α. In the present embodiment, the SOC of the battery pack 100 is calculated (estimated) based on SOC-OCV characteristics (SOC-OCV curve). FIG. 3 is a graph illustrating the SOC-OCV characteristics. In FIG. 3, the axis of ordinate represents an OCV of the battery pack 100 (battery cell) and the axis of abscissa represents the SOC thereof. In FIG. 3, the solid line represents the characteristics of an LFP battery, and the broken line represents the characteristics of an NMC battery. In the relationship between the OCV and the SOC (hereinafter, this relationship will be referred to also as “OCV curve”) of the LFP battery, there is a region where changes in the OCV curve are minute (voltage flat region: plateau region). In the LFP battery, in a region where the SOC is lower than in the plateau region (in FIG. 3, a region where the SOC is equal to or lower than A) and a region where the SOC is higher than in the plateau region (in FIG. 3, a region where the SOC is equal to or higher than B), the OCV changes significantly in response to changes in the SOC. These regions will be referred to also as non-plateau regions.

In the LFP battery, the accuracy of calculation of the SOC using the SOC-OCV characteristics is low in the plateau region. In the LFP battery, the accuracy of calculation of the SOC using the SOC-OCV characteristics is high in the non-plateau regions. The predetermined value α is set to a value lower than A in FIG. 3 to allow fora case where the battery pack 100a is an LFP battery. The predetermined value α may be 0 [%]. The predetermined value α may be set to the same value regardless of the battery type of the battery pack. Using the voltage VB of the battery pack 100a as a parameter, the SOC of the battery pack 100a is calculated from the SOC-OCV characteristics of FIG. 3.

When the SOC of the battery pack 100a is equal to or lower than the predetermined value α, an affirmative determination is made and the process moves to S13. When the SOC of the battery pack 100a is higher than the predetermined value α, a negative determination is made and the process returns to S11, where the discharge of the battery pack 100a is executed until the SOC becomes equal to or lower than the predetermined value α.

In S13, the discharge of the battery pack 100a is stopped and the charge of the battery packs 100b to 100d is stopped. The charge and the discharge are stopped as the operation of the DC-DC converters 110a to 110d is stopped.

In S14, it is determined whether a predetermined time T1 has elapsed since the discharge of the battery pack 100a has stopped. When the predetermined time T1 has elapsed, an affirmative determination is made and the process moves to S15. When the predetermined time T1 has not elapsed, the determination of S14 is repeatedly processed. The predetermined time T1 is set, for example, as a time enough for an influence of concentration polarization etc. to become small after the discharge of the battery pack 100a has stopped.

In S15, the SOC that has been calculated from the SOC-OCV characteristics using the voltage VB of the battery pack 100a as a parameter is stored as SOCs.

In the subsequent S16, charge of the battery pack 100a is performed, while the current IB is integrated to calculate an integrated current amount EIB. The control device 200 operates the DC-DC converters 110a to 110d so as to supply the electricity stored in the other battery packs 100b to 100d to the battery pack 100a as indicated by the long dashed double-short dashed line in FIG. 1. Thus, the electricity discharged from the other battery packs 100b to 100d is charged to the battery pack 100a. The integrated current amount ΣIB [Ah] corresponds to a value obtained by integrating the current IB with respect to time, and is one example of “the electricity that has been charged to the first battery pack” of the present disclosure.

In S17, it is determined whether the SOC of the battery pack 100a is equal to or higher than a predetermined value β. The predetermined value β is set to a value higher than B in FIG. 3 to allow for a case where the battery pack 100a is an LFP battery. The predetermined value β may be 100 [%]. The predetermined value β may be set to the same value regardless of the battery type of the battery pack.

When the SOC of the battery pack 100a is equal to or higher than the predetermined value β, an affirmative determination is made and the process moves to S18. When the SOC of the battery pack 100a is lower than the predetermined value β, a negative determination is made and the process returns to S16, where the charge of the battery pack 100a is executed until the SOC becomes equal to or higher than the predetermined value β.

In S18, the charge of the battery pack 100a is stopped and the discharge of the battery packs 100b to 100d is stopped. The charge and the discharge are stopped as the operation of the DC-DC converters 110a to 110d is stopped. The integration of the current IB is ended, and the integrated current amount ΣIB is stored.

In S19, it is determined whether a predetermined time T2 has elapsed since the charge of the battery pack 100a has stopped. When the predetermined time T2 has elapsed, an affirmative determination is made and the process moves to S20. When the predetermined time T2 has not elapsed, S19 is repeatedly processed. The predetermined time T2 is set, for example, as a time enough for an influence of concentration polarization etc. to become small after the charge of the battery pack 100a has stopped.

In S20, the SOC that has been calculated from the SOC-OCV characteristics using the voltage VB of the battery pack 100a as a parameter is stored as SOCe.

In S21, a full charge capacity Fc [Ah] of the battery pack 100a is calculated from the following Formula (1):

$$Fc = \sum \vert B / ( ( SOCe - SOCs ) / 100 ) \qquad ( 1 )$$

For example, when the SOCe is 100 [%] and the SOCe is 0 [%], the calculation result is Fc=ΣIB.

When S21 has been processed, the current routine ends. In the next routine, in S10, a battery pack 100 of which the full charge capacity has not been measured (e.g., the battery pack 100b) may be selected and the same process may be performed. The process may be repeated until the full charge capacities of all the battery packs 100 have been measured.

In the present embodiment, the control device 200 discharges the battery pack 100a selected from the battery packs 100a to 100d until the SOC of the battery pack 100a becomes equal to or lower than the predetermined value α by operating the DC-DC converters 110a to 110d so as to supply electricity from the battery pack 100a to the battery packs 100b to 100d. After the discharge of the battery pack 100a, the control device 200 charges the battery pack 100a until the SOC of the battery pack 100a becomes equal to or higher than the predetermined value β by operating the DC-DC converters 110a to 110d so as to supply electricity from the battery packs 100b to 100d to the battery pack 100a.

The control device 200 calculates the full charge capacity Fc of the battery pack 100a based on the electricity that has been charged to the battery pack 100a (integrated current amount ΣIB) while the SOC of the battery pack 100a has changed from the predetermined value α to the predetermined value β. The full charge capacity Fc of the battery pack 100a is obtained by exchanging electricity among the battery packs 100a to 100d included in the battery system 1 so as to charge and discharge the battery pack 100a. Thus, a decrease in the amount of electricity stored in the battery system 1 can be avoided when measuring the full charge capacity Fc of the battery pack 100a.

In the present embodiment, when the battery pack 100 is an LFP battery, the predetermined value α and the predetermined value β are set as values in the non-plateau regions that are a low-SOC region and a high-SOC region. Thus, the SOCs and the SOCe can be accurately calculated, and therefore the full charge capacity Fc can be accurately measured. In addition, a large difference between the SOCs and the SOCe can be secured, which allows the full charge capacity Fc to be accurately calculated using Formula (1) above.

In the present embodiment, charge and discharge of the battery packs 100a to 100d are performed by operating the DC-DC converters 110a to 110d that are respectively provided for the battery packs 100a to 100d. Thus, electricity can be controlled for each of the battery packs 100a to 100d, allowing for good controllability. Even when there is a difference in voltage among the battery packs 100a to 100d, return of the current can be avoided.

### Embodiment 2

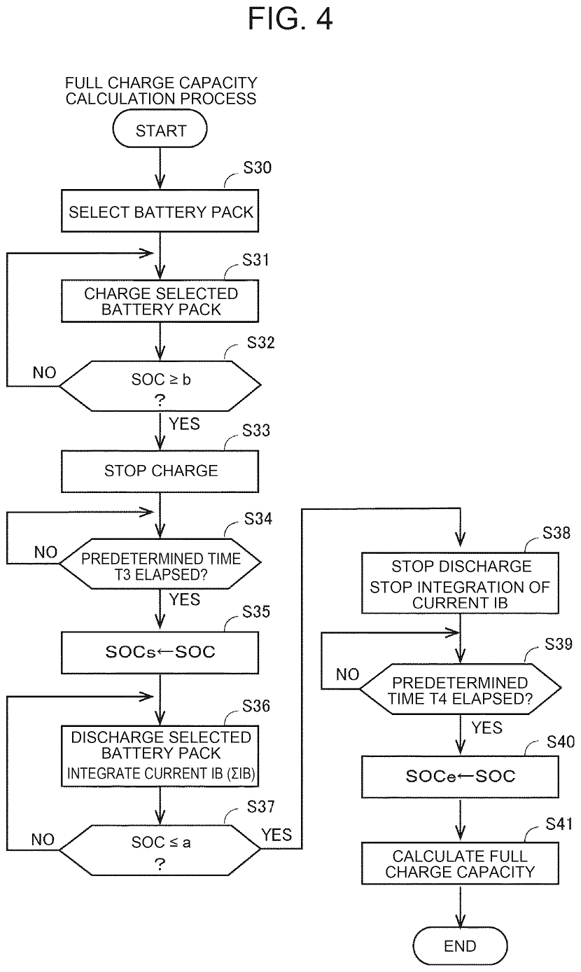

In the above-described embodiment, the full charge capacity is calculated using the integrated current amount ΣIB during charge of the selected battery pack 100. In Embodiment 2, the full charge capacity is calculated using the integrated current amount ΣIB during discharge of the selected battery pack 100. FIG. 4 is a flowchart showing one example of a full charge capacity calculation process that is executed in the control device 200 in Embodiment 2. This flowchart is executed when exchange of electricity is not being performed between the battery system 1 and the external system 2 (PCS 10) (when charge and discharge are not being performed between the battery system 1 and the external system 2).

In S30, a battery pack 100 of which the full charge capacity is to be measured is selected. The selection of the battery pack 100 may be the same as in S10, and in the present embodiment, first, the battery pack 100a is selected.

In S31, charge of the battery pack 100a is performed. To charge the battery pack 100a, as with the charge in S16, the DC-DC converters 110a to 110d are operated so as to supply the electricity stored in the other battery packs 100b to 100d to the battery pack 100a as indicated by the long dashed double-short dashed line in FIG. 1.

In S32, it is determined whether the SOC of the battery pack 100a is equal to or higher than a predetermined value b. The predetermined value b may be the same value as the predetermined value β in S17. The predetermined value b may be 100 [%]. When the SOC of the battery pack 100a is equal to or higher than the predetermined value b, an affirmative determination is made and the process moves to S33. When the SOC of the battery pack 100a is lower than the predetermined value b, a negative determination is made and the process returns to S31, where the charge of the battery pack 100a is executed until the SOC becomes equal to or higher than the predetermined value b.

In S33, the charge of the battery pack 100a is stopped and the discharge of the battery packs 100b to 100d is stopped, and the process moves to S34. In S34, it is determined whether a predetermined time T3 has elapsed since the charge of the battery pack 100a has stopped. When the predetermined time T3 has elapsed, an affirmative determination is made and the process moves to S35. When the predetermined time T3 has not elapsed, S34 is repeatedly processed. The predetermined time T3 is the same value as the predetermined time T2 in S19.

In S35, the SOC that has been calculated from the SOC-OCV characteristics using the voltage VB of the battery pack 100a as a parameter is stored as the SOCs and the process moves to S36.

In S36, discharge of the battery pack 100a is performed, while the current IB is integrated to calculate the integrated current amount ΣIB. To discharge the battery pack 100a, as in S11, the DC-DC converters 110a to 110d are operated so as to supply the electricity stored in the battery pack 100a to the battery packs 100b to 100d as indicated by the long dashed short dashed line in FIG. 1. The current IB detected in the monitoring module 120 is detected as a negative (−) value during discharge, and therefore the integrated current amount ΣIB [Ah] is integrated as a negative value.

In S37, it is determined whether the SOC of the battery pack 100a is equal to or lower than a predetermined value a. The predetermined value a may be the same value as the predetermined value α in S12. The predetermined value α may be 0 [%]. When the SOC of the battery pack 100a is equal to or lower than the predetermined value a, an affirmative determination is made and the process moves to S38. When the SOC is higher than the predetermined value a, a negative determination is made and the process returns to S36, where the discharge of the battery pack 100a is executed until the SOC becomes equal to or lower than the predetermined value a.

In S38, the discharge of the battery pack 100a is stopped and the charge of the battery packs 100b to 100d is stopped. The integration of the current IB is ended, and the integrated current amount ΣIB is stored.

In S39, it is determined whether a predetermined time T4 has elapsed since the charge of the battery pack 100a has stopped. When the predetermined time T4 has elapsed, an affirmative determination is made and the process moves to S40. When the predetermined time T4 has not elapsed, S39 is repeatedly processed. The predetermined time T4 may be the same value as the predetermined time T1 in S13.

In S40, the SOC that has been calculated from the SOC-OCV characteristics using the voltage VB of the battery pack 100a as a parameter is stored as the SOCe.

In S41, the full charge capacity Fc [Ah] of the battery pack 100a is calculated from Formula (1) above. The integrated current amount ΣIB is a negative value and the value of (SOCe-SOCs) is also negative, and therefore the full charge capacity Fc is a positive value.

When S41 has been processed, the current routine ends. As with the process of FIG. 2, the process may be repeated until the full charge capacities of all the battery packs 100 have been measured.

In Embodiment 2, the control device 200 calculates the full charge capacity Fc of the battery pack 100a based on the electricity that has been discharged from the battery pack 100a (integrated current amount ΣIB) while the SOC of the battery pack 100a has changed from the predetermined value b to the predetermined value α. The full charge capacity Fc of the battery pack 100a is obtained by exchanging electricity among the battery packs 100a to 100d included in the battery system 1 so as to charge and discharge the battery pack 100a. Thus, a decrease in the amount of electricity stored in the battery system 1 can be avoided when measuring the full charge capacity Fc of the battery pack 100a.

In Embodiment 2, as in Embodiment 1, the SOCs and the SOCe can be accurately calculated and a large difference between the SOCs and the SOCe can be secured, which allows the full charge capacity Fc to be accurately calculated. Since the DC-DC converters 110a to 110d are respectively provided for the battery packs 100a to 100d, controllability is good, and even when there is a difference in voltage among the battery packs 100a to 100d, return of the current can be avoided.

### Modified Example

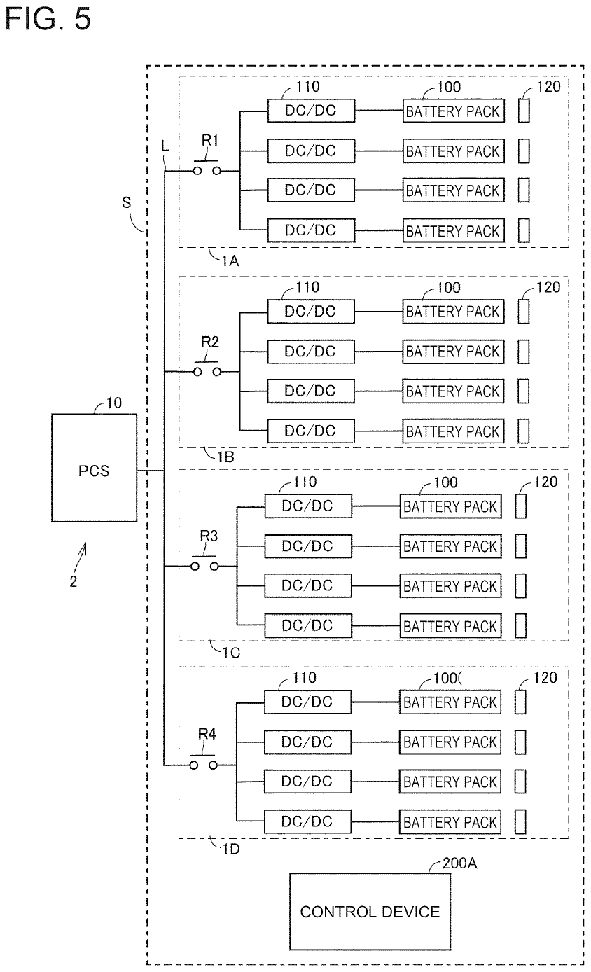

FIG. 5 is a schematic configuration diagram of a battery system S in a modified example. The battery system S includes a plurality of sub-battery systems 1A to 1D. The sub-battery systems 1A to 1D are connected, in parallel to one another, to the external system 2 (PCS 10). (In FIG. 5, the photovoltaic power generation device 20, the load 30, and the power grid PG are omitted.)

The sub-battery systems 1A to 1D are components which are similar to the battery system 1 in the embodiments, and in each of which a plurality of battery packs 100 and the DC-DC converters 110 corresponding respectively to the battery packs 100 are connected in parallel. The sub-battery systems 1A to 1D include corresponding relays R1 to R4, respectively, and are connected, in parallel to one another, to the PCS 10 through the relays R1 to R4. A control device 200A controls operation of the DC-DC converters 110 and opening and closing of the relays R1 to R4.

In this modified example, when executing the full charge capacity calculation process of FIG. 2 or FIG. 4, one of the relays R1 to R4 is opened that corresponds to one of the sub-battery systems 1A to 1D that includes the battery pack 100 of which the full charge capacity is to be measured. For example, when calculating the full charge capacity of the battery pack 100 included in the sub-battery system 1A, the relay R1 is opened and the relays R2 to R4 are closed. Thus, connection between the sub-battery system 1A and the PCS 10 is cut off, which allows the full charge capacity calculation process of FIG. 2 or FIG. 4. Since the sub-battery systems 1B to 1D are connected to the PCS 10, electricity can be exchanged between the external system 2 and the sub-battery systems 1B to 1D. The number of the sub-battery systems 1A to 1D is arbitrary and may be any number larger than one.

In this modified example, it is possible to measure the full charge capacity of the battery pack 100 by executing the full charge capacity calculation process of FIG. 2 or FIG. 4 while exchanging electricity between the battery system S and the external system 2.

The embodiments disclosed this time should be construed as being in every respect illustrative and not restrictive. The scope of the present disclosure is indicated not by the description of the embodiments given above but by the claims, and is intended to include all changes within the meaning and range of equivalents of the claims.

What is claimed is:

1. A battery system that performs charge and discharge between the battery system and an external system, the battery system comprising:
a plurality of battery packs that is connected, in parallel to one another, to the external system;
a plurality of direct current-direct current converters that is provided so as to correspond to the battery packs and is each disposed in a power line connecting the corresponding battery pack with the external system; and
a control device that controls the direct current-direct current converters,
wherein the control device
discharges a first battery pack selected from the battery packs until a state of charge of the first battery pack becomes equal to or lower than a first predetermined value by operating the direct current-direct current converters corresponding respectively to the first battery pack and other battery packs so as to supply electricity from the first battery pack to the other battery packs;
after the discharge, charges the first battery pack until the state of charge of the first battery pack becomes equal to or higher than a second predetermined value by operating the direct current-direct current converters so as to supply electricity from the other battery packs to the first battery pack; and
calculates a full charge capacity of the first battery pack based on the electricity that has been charged to the first battery pack during the charge.

2. A battery system that performs charge and discharge between the battery system and an external system, the battery system comprising:
a plurality of battery packs that is connected, in parallel to one another, to the external system;
a plurality of direct current-direct current converters that is provided so as to correspond to the battery packs and is each disposed in a power line connecting the corresponding battery pack with the external system; and
a control device that controls the direct current-direct current converters,
wherein the control device
charges a first battery pack selected from the battery packs until a state of charge of the first battery pack becomes equal to or higher than a third predetermined value by operating the direct current-direct current converters corresponding respectively to the first battery pack and other battery packs so as to supply electricity from the other battery packs to the first battery pack;
after the charge, discharges the first battery pack until the state of charge of the first battery pack becomes equal to or lower than a fourth predetermined value by operating the direct current-direct current converters so as to supply electricity from the first battery pack to the other battery packs; and
calculates a full charge capacity of the first battery pack based on the electricity that has been discharged from the first battery pack during the discharge.

3. The battery system according to claim 1, wherein the state of charge of the first battery pack is estimated based on a voltage of the first battery pack.

4. The battery system according to claim 2, wherein the state of charge of the first battery pack is estimated based on a voltage of the first battery pack.
